(19) United States
(12) Patent Application Publication
(10) Pub. No.: US 2022/0033969 A1
(43) Pub. Date: Feb. 3, 2022

(54) COATING APPARATUS

(71) Applicant: LG CHEM, LTD., Seoul (KR)

(72) Inventors: Sang Joon Park, Daejeon (KR); Ki Hwan Kim, Daejeon (KR); Eun Jeong Lee, Daejeon (KR); Yong Chan Kim, Daejeon (KR)

(21) Appl. No.: 17/280,054

(22) PCT Filed: Jan. 23, 2020
(86) PCT No.: PCT/KR2020/001174

§ 371 Date: Mar. 25, 2021

(30) Foreign Application Priority Data
Jan. 31, 2019 (KR) 10-2019-0012719

(51) Int. Cl. C23C 16/455; C23C 16/44

(52) U.S. Cl. CPC C23C 16/45551; C23C 16/4417

(57) ABSTRACT

A coating apparatus, and particularly, an atomic layer deposition apparatus. The atomic layer deposition apparatus consecutively coats the surfaces of powder particles with different kinds of materials.

### CROSS-REFERENCE TO RELATED APPLICATIONS

This application is a U.S. national stage of international Application No. PCT/KR2020/001174 filed Jan. 23, 2020, and claims benefit of priority from Korean Patent Application No. 10-2019-0012719 filed Jan. 31, 2019, the contents of which are incorporated as if fully set forth herein.

### TECHNICAL FIELD

The present invention relates to a coating apparatus, such as an atomic layer deposition apparatus, and particularly, to an atomic layer deposition apparatus for powder coating, which apparatus can be used for various deposition methods such as a chemical vapor deposition method, a molecular layer deposition method, and a combination method thereof, and which perform deposition using a gaseous flow.

### BACKGROUND

An atomic layer deposition (ALD) technology is a technology for forming a film on a substrate by sequentially providing chemical materials in a gas phase, and this technology is applied to various fields.

There is an emerging necessity for manufacturing conformal coating on surfaces of powder particles. For example, using an ultra-thin coating technology to coat battery active material particles or catalyst particles with a protective layer improves durability and performance of existing particles without degrading other properties of the battery active material particles or catalyst particles.

A coating technology using an atomic layer deposition method is applied to the surfaces of particles to prepare an ultra-thin conformal coating. The atomic layer deposition method is the most suitable technology for preparing an ultra-thin film coating on the surfaces of the powder particles because thickness control and precision can be achieved by controlling a reaction cycle and the coating is formed due to a surface reaction when reaction source gases are alternately sprayed to achieve a highly conformal coating property.

However, the existing coating apparatus for atomic layer deposition on surfaces of powder particles is suitable for single material coating, and thus an apparatus for consecutively coating powder particles with different kinds of materials is required.

### SUMMARY

The present invention is directed to a coating apparatus capable of consecutively coating surfaces of powder particles with different kinds of materials.

One exemplary aspect of the present invention is a coating apparatus including an outer chamber including a rotating shaft, one or more reactors disposed in the outer chamber and connected to the rotating shaft, the rotating shaft disposed to be movable to a first position and a second position in the outer chamber, and the outer chamber including accommodation spaces, a first deposition part including a first supply part, which is provided to be detachably coupled to the reactor positioned at the first position in the outer chamber and sprays one or more kinds of source gases to the accommodation spaces to form a first deposition layer when installed in the reactor, and a first pumping part which is detachably coupled to the reactor connected to the first supply part and which first pumping part is configured to evacuate the accommodation spaces, and a second deposition part including a second supply part, which is detachably coupled to the reactor positioned at the second position in the outer chamber and sprays one or more kinds of source gases to the accommodation spaces to form a second deposition layer when installed in the reactor, and a second pumping part, which is detachably coupled to the reactor connected to the second supply part and which second pumping part is configured to evacuate the accommodation space.

As described above, a coating apparatus according to at least one exemplary embodiment of the present invention has the following effects.

Surfaces of powder particles can be consecutively coated with different kinds of materials using an atomic layer deposition method.

Specifically, the surfaces of the powder particles can be consecutively coated with different kinds of materials as the reactors rotate to move to deposition positions around a rotating shaft.

In addition, when the same powder particles are charged in the plurality of reactors, the same powder particles can be simultaneously coated with the different kinds of materials because different materials are deposited in each of the reactors.

In addition, when different basic materials are charged in the plurality of reactors, coating with the same or different materials can be performed in each of the reactors.

### BRIEF DESCRIPTION OF DRAWINGS

FIG. 1 is a schematic illustration of a coating apparatus according to one exemplary embodiment of the present invention.

FIG. 2 is a schematic illustration of the movement of reactors in an outer chamber.

FIG. 3 is a schematic illustration of one operating state of the coating apparatus according to one exemplary embodiment of the present invention.

FIG. 4 is a schematic illustration of the main components of the coating apparatus according to one exemplary embodiment of the present invention.

### DETAILED DESCRIPTION

Hereinafter, a coating apparatus (also referred to as an “atomic layer deposition apparatus”) will be described in detail with reference to the accompanying drawings.

In addition, components that are the same or correspond to each other regardless of reference numerals are referred to by the same or similar reference numerals and redundant descriptions thereof will be omitted, and sizes and shapes of the illustrated components may be exaggerated or reduced for convenience of description.

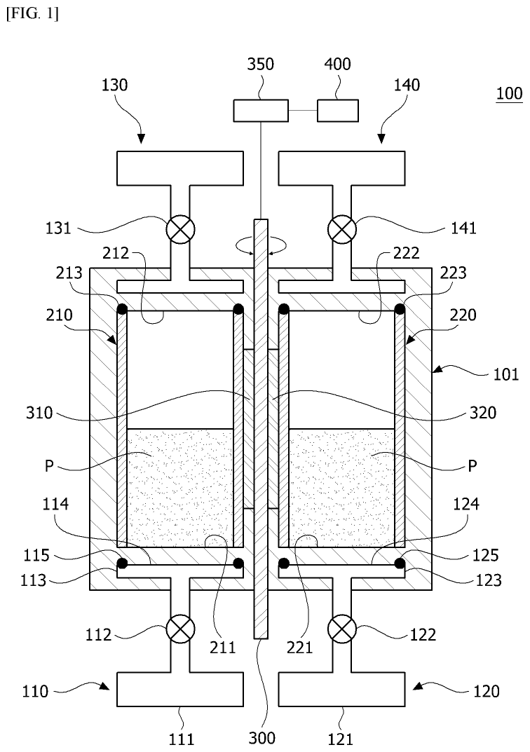

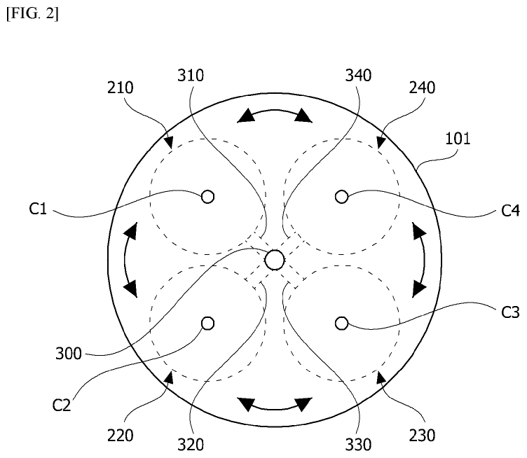

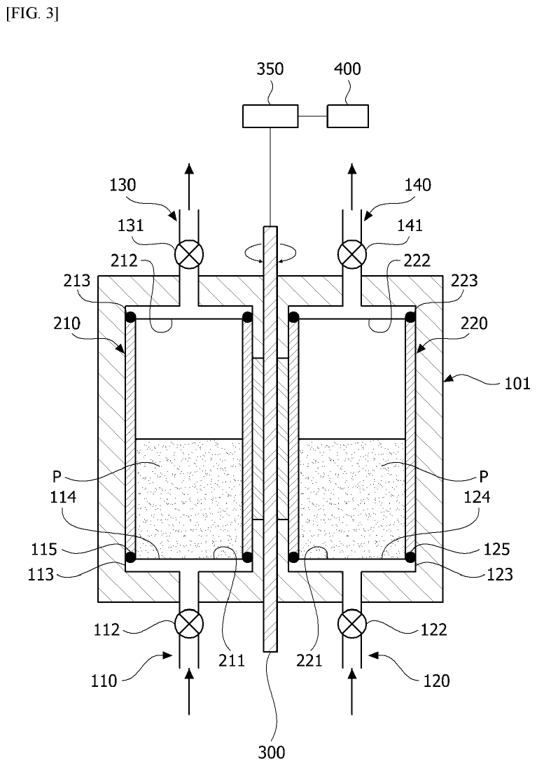

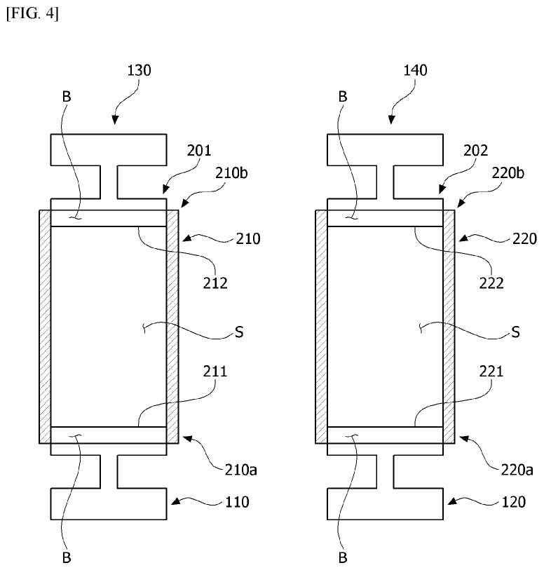

FIG. 1 is a schematic illustration of a coating apparatus 100 according to one exemplary embodiment of the present invention, FIG. 2 is a schematic illustration of the movement of reactors 210, 220, 230, and 240 in an outer chamber 101, FIG. 3 is a schematic illustration of one operation state of the coating apparatus according to one exemplary embodiment of the present invention, and FIG. 4 is a schematic illustration of the main components of the coating apparatus according to one exemplary embodiment of the present invention.

The coating apparatus 100 (hereinafter, also referred to as “atomic layer deposition apparatus”) may be used to coat a surface of the powder particles P. The atomic layer deposition apparatus 100 includes an outer chamber 101, one or more reactors 210, 220, 230, and 240, first deposition parts 110 and 130, and second deposition parts 120 and 140.

The atomic layer deposition apparatus 100 includes the outer chamber 101 having a rotating shaft. The outer chamber 101 may include a center shaft 300 and may have, for example, a cylindrical shape having a central axis. The center shaft 300 may be rotatably disposed in the outer chamber 101, and the center shaft 300 may be the rotating shaft.

A predetermined space is provided in the outer chamber 101, and one or more reactors, which will be described below, are disposed around the center shaft 300 in a predetermined space in a circumferential direction. As illustrated in FIGS. 1 and 2, a plurality of reactors, for example, four reactors, may be disposed around the center shaft 300 in the circumferential direction.

The atomic layer deposition apparatus 100 may include a plurality of reactors 210, 220, 230, and 240 disposed in the outer chamber 101. Each of the plurality of reactors 210, 220, 230, and 240 is disposed around the center shaft of the outer chamber 101 to be movable to a first position and a second position in the outer chamber 101 in a circumferential direction. One or more reactors may be disposed in the outer chamber 101.

As illustrated in FIG. 2, the first position and the second position in the specification denote arbitrary positions which are sequentially positioned in a circumferential direction (a clockwise direction or counterclockwise direction in FIG. 2) around the center shaft of the outer chamber 101. For example, when the plurality of reactors 210, 220, 230, and 240 are referred to as first to fourth reactors 210, 220, 230, and 240, respectively, a region in which the first reactor 210 is positioned in the outer chamber 101 may be referred to as the first position, and a region in which the second reactor 220 is positioned in the outer chamber 101 may be referred to as the second position.

In addition, each of the reactors may rotate to move to a predetermined position around the center shaft of the outer chamber 101 in a circumferential direction. To this end, the plurality of reactors 210, 220, 230, and 240 are connected to a first driving part 350 such as a motor. The first driving part 350 may be connected to a controller 400 and the first driving part may be controlled by the controller 400.

Specifically, the center shaft 300 is connected to the first driving part 350 and rotated by the first driving part 350. In addition, the reactors 210, 220, 230, and 240 may be connected to the center shaft 300 through connecting members 310, 320 330, and 340, respectively. In addition, the reactors 210, 220, 230, and 240 may be fixed integrally with the connecting members 310, 320 330, and 340, or the reactors 210, 220, 230, and 240 may be detachably installed on the connecting members 310, 320 330, and 340.

Each of the reactors 210, 220, 230, and 240 has an accommodation space configured to accommodate the powder particles P. In addition, each of the reactors 210, 220, 230, and 240 may have a cylindrical shape having a center shaft C1, C2, C3, and C4, respectively.

The atomic layer deposition apparatus 100 includes a first deposition part 201 and a second deposition part 202. In the first deposition part 201, one or more kinds of source gases may be sprayed to form a first deposition layer on the surface of the powder, and in the second deposition part 202, one or more kinds of source gases may be sprayed to form a second deposition layer on the surface of the powder. The first and second deposition parts 201 and 202 are provided to spray different deposition materials onto the powder in accommodation spaces S. That is, the first and second deposition layers of different materials may be deposited on the surface of the powder by the first and second deposition parts 201 and 202. For example, a source gas with trimethylaluminium (TMA) and H₂O may be used in the first deposition part 201, and a source gas with TiCl₄ and H₂O may be used in the second deposition part 202. In addition, various combinations of an oxide, a nitride, sulfide, and a single element may be used as source gases.

The first deposition part 201 includes a first supply part 110 provided to be detachably coupled to, for example, the reactor 210 positioned at the first position in the outer chamber 101 and configured to spray one or more kinds of source gas into the accommodation space S to form the first deposition layer when installed in the reactor and a first pumping part 130 detachably coupled to the reactor 210 connected to the first supply part 110 and configured to evacuate the accommodation space S. For example, the first pumping part 130 may apply a negative pressure to the accommodation space S to evacuate the accommodation space.

The first supply part 110 and the first pumping part 130 may come into contact with (be coupled to) or be separated from the reactor by moving vertically along the center shaft of the reactor (or outer chamber).

In addition, the first supply part 110 and the first pumping part 130 may be connected to a second driving part (for example, a motor or cylinder) to enable movement (for example, lifting).

The second deposition part 202 includes a second supply part 120 provided to be detachably coupled to, for example, the reactor 220 positioned at the second position in the outer chamber 101 and configured to spray one or more kinds of source gas into the accommodation space to form the second deposition layer when installed in the reactor 220 and a second pumping part 140 detachably coupled to the reactor 220 connected to the second supply part 120 and configured to evacuate the accommodation space. For example, the second pumping part 140 may apply a negative pressure to the accommodation space to evacuate the accommodation space S.

In addition, the second supply part 120 may come into contact with (be coupled to) or be separated from the reactor by moving vertically along the center shaft of the reactor (or outer chamber). In addition, the second pumping part 140 may come into contact with (be coupled to) or be separated from the reactor by moving vertically along the center shaft of the reactor (or outer chamber).

In addition, the second supply part 120 and the second pumping part 140 are connected to a third driving part (for example, a motor or a cylinder) for lifting.

Meanwhile, each of the reactors 210, 220, 230, and 240 includes a first end portion 210a or 220a to be selectively connected to the first or second supply part according to a position (first position or second position) in the outer chamber and a second end portion 210b or 220b, which is disposed in a direction opposite to the first end portion 210a or 220a, respectively, to be selectively connected to the first or second pumping part.

As illustrated in FIG. 4, the first end portions 210a and 220a refer to end portions at a lower side of the reactors 210 and 220, and the second end portions 210b and 220b refer to end portions at an upper side of the reactors 210 and 220, respectively. In this case, the first end portions 210a and 220a and the second end portions 210b and 220b may be open to the outside. That is, each of the reactors 210, 220, 230, and 240 may be a hollow cylinder of which upper and lower end portions are open. In this case, the accommodation space for the powder particles P is positioned between the first end portion and the second end portion.

In addition, each of the reactors may include porous meshes 211 and 221 or 212 and 222 disposed in the first end portion and the second end portion, respectively. Each of the reactors may include the porous meshes in upper and lower portions thereof to prevent powder particles P from being lost during a pumping process and a coating process of the powder particles P.

Particularly, when the first or second supply part 110 or 120 is coupled to the reactor, the porous mesh 211 or 221 at a side of the first end portion 210a or 220a, respectively, may be disposed so that a buffer space B is formed between the porous mesh 211 or 221 and the corresponding supply part 110 or 120, respectively.

In addition, when the first or second pumping part 130 or 140 is coupled to the reactor, the porous mesh 212 or 222 at a side of the second end portion 210b or 220b, respectively, may be disposed so that a buffer space B is formed between the porous mesh 212 or 222 and the corresponding pumping part 130 or 140.

A sealing member 115 or 213 disposed in a coupling region is provided at one of the first end portions of the reactor coupled to the first or second supply part, and an insertion groove into which the sealing member 115 or 213 is inserted may be provided in the remaining first end portion. Similarly, a sealing member 213 or 223 disposed in a coupling region is provided in one of the first or second pumping parts 130 or 140 and the second end portion of the reactor, and an insertion groove into which the sealing member 213 or 223 is inserted may be provided in the remaining pumping part.

That is, O-rings for sealing the reactor when the source supply part and the pumping part are in contact with the reactor may be disposed in outer upper and lower portions of the reactor, and grooves into which the O-rings are inserted may be formed therein.

As illustrated in FIG. 1, the sealing member may be provided at a side of the first or second supply part and the insertion groove may be provided at the side of the first end portion of the reactor, and in an exemplary embodiment, the sealing member is provided at the side of the first end portion and the insertion groove is provided at a side of the first or second pumping part, but the present invention is not limited thereto.

As illustrated in FIGS. 1 and 3, the first and second supply parts 110 and 120 may be positioned at lower end sides of the reactors, and the pumping parts may be positioned at upper ends of the reactors. In addition, two or more supply parts may be provided, and two or more pumping parts may also be provided. However, the supply parts and the pumping parts only move vertically along the center shaft of the outer chamber and, unlike the reactor, they do not move in a circumferential direction around the center shaft of the outer chamber.

Specifically, one reactor (first reactor) 210 may be coupled to the first supply part and the first pumping part at the first position and may move from the first position to the second position to be coupled to the second supply part and the second pumping part. In this structure, the surface of the powder particles P may be coated with different kinds of materials.

As illustrated in FIGS. 1 and 3, when the first supply part 120 and the first pumping part 130 are coupled to the reactor 210, the powder particles P may be floated by an inert gas supplied at a predetermined pressure from a lower portion of the reactor 210, and the surfaces of the powder particles P may be coated with the source (precursor) gas being supplied. In this case, the inert gas may also be supplied through the supply part in a state in which the inert gas is mixed with the source gas.

For example, the materials deposited in the first reactor 210 and the second reactor 220 positioned at the first position and the second position, respectively, may be different, and coating processes in the first and second reactors may be performed simultaneously.

In addition, since the reactors rotate around the center shaft of the outer chamber and are coupled to the first and second supply parts which supply different source gases, the surfaces of the particles may be coated with a plurality of different materials, thereby coating the surfaces of the particles with multiple layers.

The first and second supply parts 110 and 120 may include accommodation parts 111 and 121 in which two or more kinds of source gases and purge gases are accommodated, spray parts 114 and 124 coupled to the accommodation parts and configured to spray the source gases and the purge gases into the accommodation spaces, and valves 112 and 122 provided between the accommodation parts and the spray parts. The accommodation part may include a plurality of accommodation spaces partitioned from each other, and the source gases and the purge gases may be accommodated in the accommodation spaces. In addition, two kinds of source gases may be accommodated in the different accommodation spaces.

Each of the first and second supply parts may be provided to spray any one source gas, then spray a purge gas, and spray another source gas into the powder accommodation space. That is, each of the first deposition part and the second deposition part is provided to form a deposition layer on the surface of the powder P through an atomic layer deposition method.

In addition, the first and second supply parts 110 and 120 may include sealing blocks 113 and 123 for sealing the sides of the first end portions of the reactors, and the spray parts 114 and 124 for spraying the source gases into the accommodation spaces may be respectively provided in the sealing blocks 113 and 123. In addition, the sealing members or insertion grooves may be provided in the sealing blocks 113 and 123. The respective diameters of the sealing blocks 113 and 123 may be the same as the outer diameter of the reactors.

In addition, the first and second supply parts 110 and 120 include the valves 112 and 122, respectively, for supplying or blocking the source gases and the purge gases.

In addition, the first and second pumping parts 130 and 140 include valves 131 and 141, respectively, for exhausting or blocking the gases, respectively.

In addition, the reactor may be provided to move from the first position to the second position when the first supply part and the first pumping part are separated from the reactor, and each of the valves may be maintained in a closed state when the first supply part and the first pumping part are separated from the reactor. Similarly, the reactor may be provided to move from the second position to the first position when the second supply part and the second pumping part are separated from the reactor, and each of the valves may be maintained in the closed state when the second supply part and the second pumping part are separated from the reactor.

That is, when the reactor rotates, each of the valves of the supply part and the pumping part is maintained in a closed state.

In addition, after a deposition process has been completed in each of the first and second deposition parts, a pressure inside the reactor and a pressure inside the outer chamber need to be synchronized to separate the supply part and the pumping part from the reactor when the reactor rotates.

The above-described exemplary embodiments of the present invention are disclosed to exemplify the present invention and may be variously changed, modified, and added to by those skilled in the art within the spirit and scope of the present invention, and such changes, modifications, and additions may fall within the scope of the appended claims.

According to one exemplary embodiment of the present invention, surfaces of powder particles may be consecutively coated with different kinds of materials through an atomic layer deposition method using a coating apparatus described herein.

1. A coating apparatus comprising:
an outer chamber including a rotating shaft;
one or more reactors disposed in the outer chamber, wherein the one or reactors are connected to the rotating shaft and are disposed to be movable to a first position and a second position in the outer chamber, and wherein each of the one or more reactors includes an accommodation space to accommodate powder particles;
a first deposition part including a first supply part and a first pumping part, wherein the first deposition part is detachably coupled to the reactor positioned at the first position in the outer chamber, and wherein the first deposition part sprays one or more kinds of source gases into a first accommodation space, and wherein first pumping part is detachably coupled to the reactor connected to the first supply part and is configured to evacuate the first accommodation space; and
a second deposition part including a second supply part and a second pumping part, wherein the second deposition part is detachably coupled to the reactor positioned at the second position in the outer chamber, and wherein the second deposition part sprays one or more kinds of source gases into a second accommodation space to form a second deposition layer, and wherein the second pumping part is detachably coupled to the reactor connected to the second supply part and is configured to evacuate the second accommodation space.

2. The coating apparatus of claim 1, wherein the first deposition part and the second deposition part supply the different source gases to the accommodation spaces of the reactors.

3. The coating apparatus of claim 1, wherein each of the one or more reactors includes:
a first end portion configured to be selectively connected to the first supply part or the second supply part; and
a second end portion disposed in a direction opposite to the first end portion and configured to be selectively connected to the first pumping part or the second pumping part,
wherein the first end portion and the second end portion are open to the outside, and
wherein the accommodation space in each of the one or more reactors is positioned between the first end portion and the second end portion.

4. The coating apparatus of claim 3, wherein each of the one or more reactors further includes a porous mesh disposed on each of the first end portion and the second end portion.

5. The coating apparatus of claim 4, wherein, when the first supply part or the second supply part is coupled to the reactor, the porous mesh at a side of the first end portion is disposed to form a buffer space between the porous mesh and the corresponding first supply part or the second supply part.

6. The coating apparatus of claim 4, wherein, when the first pumping part or the second pumping part is coupled to the reactor, the porous mesh at a side of the second end portion is disposed to form a buffer space between the porous mesh and the corresponding first pumping part or the second pumping part.

7. The coating apparatus of claim 3, further comprising:
a sealing member disposed in a coupling region between one of the first supply part or the second supply part and the first end portion of the reactor,
a wherein the sealing member is inserted in an insertion groove provided in the other of the first supply part or the second supply part.

8. The coating apparatus of claim 3, further comprising:
a sealing member disposed in a coupling region between one of the first pumping part or the second pumping part and the second end portion of the reactor,
wherein the sealing member is inserted in an insertion groove provided in the other of the first pumping part or the second pumping part.

9. The coating apparatus of claim 1, wherein each of the first supply part and the second supply part includes:
an accommodation part configured to accommodate two or more kinds of source gases and purge gases;
a spray part connected to the accommodation part and configured to spray the source gases and the purge gases into the accommodation space; and
a valve provided between the accommodation part and the spray part.

10. The coating apparatus of claim 9, wherein each of the first supply part and the second supply part is provided to sequentially spray into the accommodation part: any one source gas, the purge gas, and another source gas.

11. The coating apparatus of claim 1, wherein the reactor is provided to move from the first position to the second position in a state in which the first supply part and the first pumping part are separated from the reactor.

12. The coating apparatus of claim 11, wherein, a valve is maintained in a closed state when the first supply part is separated from the reactor.
